(19) United States
(12) Patent Application Publication
(10) Pub. No.: US 2013/0137196 A1
(43) Pub. Date: May 30, 2013

(54) METHOD FOR MONITORING DEVICES IN SEMICONDUCTOR PROCESS

(71) Applicant: Shanghai Huali Microelectronics Corporation, Shanghai (CN)

(72) Inventors: Hunglin CHEN, Shanghai (CN); Kai WANG, Shanghai (CN); Lujun ZHU, Shanghai (CN); Qiliang NI, Shanghai (CN); Yin LONG, Shanghai (CN); Mingsheng GUO, Shanghai (CN)

(73) Assignee: SHANGHAI HUALI MICROELECTRONICS CORPORATION, Shanghai (CN)

(21) Appl. No.: 13/687,148

(22) Filed: Nov. 28, 2012

(30) Foreign Application Priority Data
Nov. 28, 2011 (CN) 201110384000.2

(51) Int. Cl. H01L 21/66

(52) U.S. Cl. CPC H01L 22/10
USPC 438/14

(57) ABSTRACT

The invention provides a method for monitoring devices in semiconductor process comprising: Step a, designing a sampling plan with fixed sample size before the beginning of the semiconductor process; Step b, determining whether to sample the wafers according to the sampling plan and dispatching the wafers to be sampled to each process device before the beginning of the process step, wherein the process device is used for performing the process step; Step c, performing the process step; Step d, sampling the wafers according to the sampling plan, and performing in-line inspection to the sampled wafers according to the sampling results; Step e, repeating Step b to Step d until all the process steps are completed; Step f, performing e-test to all the wafers. According to the method, the potential risk during the semiconductor process can be minimized through the coordination of the sampling plan and the dynamic risk flag.

### CROSS-REFERENCE TO RELATED APPLICATION

This application claims the priority benefit of China application serial no. 201110384000.2, filed Nov. 28, 2011. All disclosure of the China application is incorporated herein by reference.

### FIELD OF THE INVENTION

The present invention relates to a monitoring method in semiconductor manufacturing process, and more particularly to a method for monitoring devices in semiconductor.

### BACKGROUND OF THE INVENTION

The fabrication of the semiconductor integrated circuits involves hundreds of process steps and any of these steps out of monitoring may cause end-of-line IC fail even other steps are well controlled. Therefore, monitoring each process step and performing early warnings is one of the critical issues for semiconductor integrated process.

The conventional semiconductor factories adopt off-line monitoring and in-line monitoring to inspect the process tool performance during the operation. However, both the monitoring methods have limitations and risk periods which cause uncertainties in production. Off-line monitoring can only be implemented when the tool is not in operation, thus the frequency of monitoring is low and the uncertainties in production cannot be monitored in time. In-line monitoring is part of the whole process but usually cannot inspect all the wafers. On one hand, the wafers are inspected according to a designed sampling plan after arriving at the inspection point and the wafers not conforming to the sampling plan will skip to a subsequent main process point without being inspected. On the other hand, after arriving at the main process point, the wafers will select a process tool at random. Therefore, wafers processed by a certain process tool may never be inspected which causes the process tool out of monitoring for a time and enlarges the risk.

Consequently, conventional semiconductor factories utilizing the sampling inspection method mentioned above may take the risk generated by the large amount of wafers which skip the inspection in production.

The U.S. Pat. No. 6,408,219 “FAB yield enhancement system” discloses a system and method for identifying the sources of wafer defects and using the defect information to control the fabrication process. The U.S. Pat. No. 7,117,057, “yield patrolling system” discloses a system for monitoring yield of a manufacturing line such as an integrated circuit fabrication line. However, the dispatch of the process tools is not mentioned in these patents.

### SUMMARY OF THE INVENTION

Accordingly, at least one object of the present invention is to provide a method for monitoring devices in semiconductor process to enhance the product yield.

To achieve these and other advantages and in accordance with the object of the invention, as embodied and broadly described herein, the invention provides a method for monitoring devices in semiconductor process comprising:

Step a, designing a sampling plan with fixed sample size before the beginning of the semiconductor process;

Step b, determining whether to sample the wafers according to the sampling plan and dispatching the wafers to be sampled to each process device evenly before the beginning of the process step, wherein the process device is used for performing the process step;

Step c, performing the process step;

Step d, sampling the wafers according to the sampling plan, and performing in-line inspection to the sampled wafers according to the sampling results;

Step e, repeating Step b to Step d until all the process steps are completed;

Step f, performing e-test to all the wafers.

According to the concept of the present invention, the sampling plan varies with the process steps.

According to the concept of the present invention, further comprising dispatching a risk flag to the wafers according to a predetermined rule before sampling; adjusting the sampling plan to sample the wafers to be sampled in step b as well as the wafers with the risk flag.

According to the concept of the present invention, the predetermined rule comprises:

Step a1, withdrawing all the risk flags after performing the process step and before sampling;

Step a2, dispatching the risk flag to potential not-good wafers processed by the performed process step before sampling.

According to the concept of the present invention, the predetermined rule comprises:

Step a11, after performing the process step and before sampling, dispatching the risk flag to potential not-good wafers processed by the performed process step;

Step a12, withdrawing all the risk flags after performing in-line inspection to the sampled wafers of step d.

According to the method for monitoring devices in semiconductor process, the sampling lot can be dispatched to each of the process devices evenly, which minimizes the potential risk in the semiconductor process.

### BRIEF DESCRIPTION OF THE DRAWINGS

The method for monitoring devices in semiconductor process in accordance with the present invention will be elucidated by reference to the following embodiments and the accompanying drawings, in which:

FIG. 1 is a flow chart of the method for monitoring devices in semiconductor process in an embodiment of the present invention;

FIG. 2 is a flow chart of the predetermined rule of the dispatch of the risk flag in an embodiment of the present invention;

FIG. 3 is a flow chart of the predetermined rule of the dispatch of the risk flag in another embodiment of the present invention.

### DETAILED DESCRIPTION OF THE EMBODIMENTS

The method for monitoring devices in semiconductor process of the present invention will be described in further details hereinafter with respect to the embodiments and the accompanying drawings.

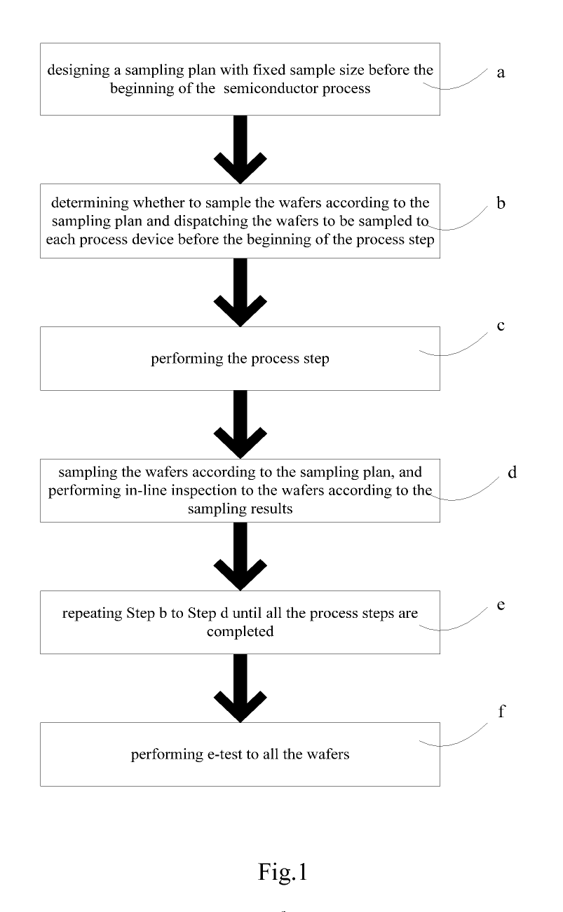

Referring to FIG. 1, the method for monitoring devices in semiconductor process comprises the following steps:

Step a, designing a sampling plan with fixed sample size before the beginning of the semiconductor process;

Step b, determining whether to sample the wafers according to the sampling plan and dispatching the wafers to be sampled to each process device evenly before the beginning of the process step, wherein the process device is used for performing the process step;

Step c, performing the process step;

Step d, sampling the wafers according to the sampling plan, and performing in-line inspection to the sampled wafers according to the sampling results;

Step e, repeating Step b to Step d until all the process steps are completed;

Step f, performing e-test to all the wafers.

Wherein, the sampling plan varies with the process steps and according to the sampling plan, the sampling lot is dispatched evenly to each process device. Therefore, the wafers processed by each process device can be sampled so as to prevent the process devices out of monitoring. Furthermore, a risk flag is dispatched to the wafers by a risk flag dispatching module according to a predetermined rule before sampling, and the sampling plan will be adjusted correspondingly so that the wafers with the risk flag will also be determined to be sampled. Therefore, during the sampling, the wafer with the risk flag as well as the wafers to be sampled in step b will be sampled according to the adjusted sampling plan.

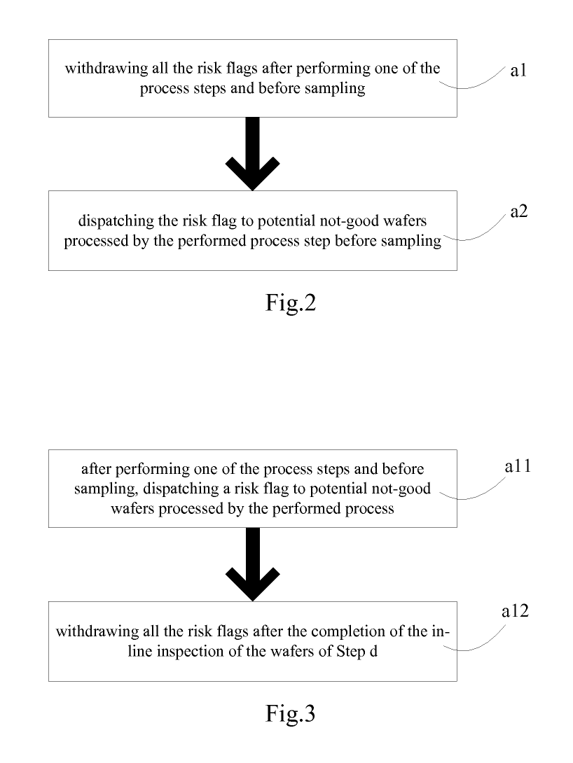

Furthermore, as shown in FIG. 2, the predetermined rule of the dispatch of the risk flag comprises the following steps:

Step a1, withdrawing all the risk flags after performing the process step and before sampling;

Step a2, dispatching the risk flag to potential not-good wafers processed by the performed process step before sampling.

Referring to FIG. 3, in another embodiment of the present invention, the predetermined rule of the dispatch of the risk flag comprises the following steps:

Step a11, after performing the process step and before sampling, dispatching the risk flag to potential not-good wafers processed by the performed process step;

Step a12, withdrawing all the risk flags after performing in-line inspection to the sampled wafers of step d.

The advantage is that the sampling plan can be varied by the dynamic risk flag, and after the completion of each process step, sampling will be performed to the potential not-good wafers processed thereby, which can evenly dispatch the sampling lot to each process step so as to minimize the potential risk period and enhance the product yield.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A method for monitoring devices in semiconductor process comprising:
Step a, designing a sampling plan with fixed sample size before the beginning of the semiconductor process;
Step b, determining whether to sample the wafers according to the sampling plan and dispatching the wafers to be sampled to each process device before the beginning of the process step, wherein the process device is used for performing the process step;
Step c, performing the process step;
Step d, sampling the wafers according to the sampling plan, and performing in-line inspection to the wafers according to the sampling results;
Step e, repeating Step b to Step d until all the process steps are completed;
Step f, performing e-test to all the wafers.

2. The method for monitoring devices in semiconductor process according to claim 1, wherein the sampling plan varies with the process steps.

3. The method for monitoring devices in semiconductor process according to claim 2, further comprising dispatching a risk flag to the wafers according to a predetermined rule before sampling; adjusting the sampling plan to sample the wafers to be sampled in step b as well as the wafers with the risk flag.

4. The method for monitoring devices in semiconductor process according to claim 3, wherein the predetermined rule comprises:
withdrawing all the risk flags after performing the process step and before sampling;
dispatching the risk flag to potential not-good wafers processed by the performed process step before sampling.

5. The method for monitoring devices in semiconductor process according to claim 3, wherein the predetermined rule comprises:
after performing the process step and before sampling, dispatching the risk flag to potential not-good wafers processed by the performed process step;
withdrawing all the risk flags after performing in-line inspection to the sampled wafers of Step d.
